(19) United States
(12) Patent Application Publication
(10) Pub. No.: US 2021/0351208 A1
(43) Pub. Date: Nov. 11, 2021

(54) ARRAY SUBSTRATE AND MANUFACTURING METHOD THEREOF

(71) Applicant: SHENZHEN CHINA STAR OPTOELECTRONICS SEMICONDUCTOR DISPLY TECHNOLOGY CO., LTD., Shenzhen (CN)

(72) Inventor: Meng CHEN, Shenzhen (CH)

(73) Assignee: SHENZHEN CHINA STAR OPTOELECTRONICS SEMICONDUCTOR DISPLY TECHNOLOGY CO., LTD., Shenzhen (CN)

(21) Appl. No.: 16/333,236

(22) PCT Filed: Sep. 7, 2018
(86) PCT No.: PCT/CN2018/104505

§ 371 Date: Mar. 14, 2019

(30) Foreign Application Priority Data
Aug. 3, 2018 (CN) 201810876711.3

(51) Int. Cl. H01L 27/12

(52) U.S. Cl. CPC H01L 27/1259; H01L 21/32134; H01L 27/124

(57) ABSTRACT

A method for manufacturing an array substrate is provided. The method includes providing a substrate comprising a base layer and a poly-silicon layer, then sequentially deposing a first metal layer and a second metal layer on the poly-silicon layer, implementing a first patterning process so that the second metal layer comprises a first area to be etched that protrudes from the third metal, implementing a second patterning process to remove first area to be etched of the third metal layer, and repeating the above steps.

### TECHNICAL FIELD

The present disclosure relates to the field of displays, and in particular to an array substrate and a manufacturing method thereof.

### BACKGROUND ART

In the advanced generation of display panels, copper materials have gradually become a substitute for traditional aluminum materials in metal lines due to their low impedance.

Copper wires each typically have a thickness of 3000 angstroms. However, with the increase of the size and resolution of the display panels, it is hard to solve other problems such as phase circuit delay by using the conventional copper wires. A usual solution is to increase the thickness of the copper wires.

In the preparation of the copper wires, the etching time of the copper wires will increase during a wet etching process due to an increased thickness of the copper wires, which in turn causes an excessively narrow width of the copper wires, resulting in an increased risk of breakage of the copper wires. However, if the etching time of the copper wires in a wet etching process is reduced, there is a risk of residue of molybdenum metal in the metal lines each of which has a copper/molybdenum structure. Therefore, it is necessary to provide a method for manufacturing an array substrate to solve the above problems.

### Technical Problem

There is a problem of residue of molybdenum metal caused by less etching time of the metal lines during a wet etching process in the manufacturing process of an array substrate.

### Technical Solutions

To achieve the above objects, the present disclosure provides the following technical solutions.

According to one aspect of the present disclosure, a method for manufacturing an array substrate is provided, including the following steps:

S10, providing a substrate including a base layer and a poly-silicon layer disposed on the base layer, and then sequentially deposing a first metal layer and a second metal layer on the poly-silicon layer;

S20, implementing a first patterning process to the first metal layer and the second metal layer so as to form a first pattern layer of first metal and a first pattern layer of second metal, wherein the pattern layer of first metal contains a first area to be etched that protrudes from the first pattern layer of second metal;

S30, implementing a second patterning process to the first pattern layer of first metal for removing the first area to be etched so as to obtain a second pattern layer of first metal;

S40, implementing a third patterning process to the second pattern layer of first metal and the first pattern layer of second metal so as to form a third pattern layer of first metal and a second metal, wherein the third pattern layer of first metal contains a second area to be etched that protrudes from the second metal; and

S50, implementing a fourth patterning process to the third pattern layer of first metal for removing the second area to be etched so as to obtain a first metal;

wherein the array substrate includes metal lines composed of the first metal and the second metal, and the metal lines are source-drain metal lines.

According to one embodiment of the present disclosure, a manufacturing of material of the first metal is molybdenum, and a manufacturing material of the second metal is copper

According to one embodiment of the present disclosure, a first photoresist layer containing an edge area that protrudes from the first pattern layer of second metal is disposed on a surface of the first pattern layer of second metal after implementing the first patterning process to the first metal layer and the second metal layer in step S20, and,

step S20 further includes: ashing the first photoresist layer to remove the edge area of the first photoresist layer after implementing the first patterning process to the first metal layer and the second metal layer.

According to one embodiment of the present disclosure, step S30 further includes: implementing the second patterning process to the first pattern layer of first metal so as to pattern the poly-silicon layer when removing the first area to be etched.

According to one embodiment of the present disclosure, step S30 includes:

etching the first pattern layer of first metal with etching gases to remove the first area to be etched,

wherein the etching gases contain a first gas and a second gas, the first gas is at least one of carbon tetrafluoride, chlorotrifluoromethane and dichlorodifluoromethane, and the second gas is oxygen.

According to one embodiment of the present disclosure, a second photoresist layer is disposed on a surface of the third pattern layer of second metal after implementing the third patterning process to the second pattern layer of first metal and the second pattern layer of second metal in step S40;

step S40 further comprises: implementing the third patterning process to the second pattern layer of first metal and the second pattern layer of second metal, and stripping the second photoresist layer.

According to one embodiment of the present disclosure, the first patterning process and the third patterning process are wet etching processes, and the second patterning process and the fourth patterning process are dry etching processes.

According to one embodiment of the present disclosure, step S50 includes:

etching the third pattern layer of first metal with etching gases to remove the second area to be etched;

wherein the etching gases contain a first gas and a second gas, the first gas is at least one of carbon tetrafluoride, chlorotrifluoromethane and dichlorodifluoromethane, and the second gas is oxygen.

According to another aspect of the present disclosure, a method for manufacturing an array substrate is further provided, which includes:

step S10, providing a substrate, and then sequentially deposing a first metal layer and a second metal layer on the substrate;

step S20, implementing a first patterning process to the first metal layer and the second metal layer so as to form a first pattern layer of first metal and a second metal, wherein the pattern layer of first metal contains a first area to be etched that protrudes from the first pattern layer of second metal; and

step S30, implementing a second patterning process to the first pattern layer of first metal for removing the first area to be etched so as to obtain a first metal;

wherein the array substrate includes gate metal lines composed of the first metal and the second metal.

According to one aspect of the present disclosure, a method for manufacturing an array substrate is provided, including the following steps:

S10, providing a substrate comprising a base layer and a poly-silicon layer disposed on the base layer, sequentially deposing a first metal layer and a second metal layer on the poly-silicon layer;

S20, implementing a first patterning process to the first metal layer and the second metal layer so as to form a first pattern layer of first metal and a first pattern layer of second metal, wherein the pattern layer of first metal contains a first area to be etched that protrudes from the first pattern layer of second metal;

S30, implementing a second patterning process to the first pattern layer of first metal for removing the first area to be etched so as to obtain a second pattern layer of first metal;

S40, implementing a third patterning process to the second pattern layer of first metal and the first pattern layer of second metal so as to form a third pattern layer of first metal and a second metal, wherein the third pattern layer of first metal contains a second area to be etched that protrudes from the second metal; and

S50, implementing a fourth patterning process to the third pattern layer of first metal for removing the second area to be etched so as to obtain a first metal;

wherein the array substrate includes metal lines composed of the first metal and the second metal.

According to one embodiment of the present disclosure, a manufacturing of material of the first metal is molybdenum, and a manufacturing material of the second metal is copper.

According to one embodiment of the present disclosure, a first photoresist layer containing an edge area that protrudes from the first pattern layer of second metal is disposed on a surface of the first pattern layer of second metal after implementing the first patterning process to the first metal layer and the second metal layer in step S20;

step S20 further includes: ashing the first photoresist layer to remove the edge area of the first photoresist layer after implementing the first patterning process to the first metal layer and the second metal layer.

According to one embodiment of the present disclosure, step S30 further includes: implementing the second patterning process to the first pattern layer of first metal so as to pattern the poly-silicon layer when removing the first area to be etched.

According to one embodiment of the present disclosure, step S30 includes:

etching the first pattern layer of first metal with etching gases to remove the first area to be etched;

wherein the etching gases contain a first gas and a second gas, the first gas is at least one of carbon tetrafluoride, chlorotrifluoromethane and dichlorodifluoromethane, and the second gas is oxygen.

According to one embodiment of the present disclosure, a second photoresist layer is disposed on a surface of the third pattern layer of second metal after implementing the third patterning process to the second pattern layer of first metal and the second pattern layer of second metal in step S40;

step S40 further includes: implementing the third patterning process to the second pattern layer of first metal and the second pattern layer of second metal, and stripping the second photoresist layer.

According to one embodiment of the present disclosure, the first patterning process and the third patterning process are wet etching processes, and the second patterning process and the fourth patterning process are dry etching processes.

According to one embodiment of the present disclosure, step S50 includes:

etching the third pattern layer of first metal with etching gases to remove the second area to be etched;

wherein the etching gases contain a first gas and a second gas, the first gas is at least one of carbon tetrafluoride, chlorotrifluoromethane and dichlorodifluoromethane, and the second gas is oxygen.

### Advantageous Effects

Advantageous effect of the present disclosure is to provide an array substrate and a manufacturing method thereof, in which residual molybdenum in metal lines is removed by dry etching process for reducing the etching time of metal lines during a wet etching process as well as the risk of molybdenum residue, such that problems of breakage of metal lines caused by excessively narrow width of metal lines can be avoided.

### BRIEF DESCRIPTION OF THE DRAWINGS

To describe the technical solutions in the embodiments of the present disclosure or in the prior art more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a flowchart illustrating a method for manufacturing an array substrate according to one embodiment of the present disclosure;

FIGS. 2a to 2f are structural views of an array substrate in manufacturing process according to one embodiment of the present disclosure;

FIG. 3 is a structural view of one metal line in step S20 in the present disclosure;

FIG. 4 is a flowchart illustrating a method for manufacturing an array substrate according to another embodiment of the present disclosure.

### DETAILED DESCRIPTION OF THE PREFERRED EMBODIMENTS

The description given below for the various embodiment is made with reference to the attached drawings to illustrate, in exemplificative form, specific embodiments of the present disclosure. Furthermore, the directional terms described in the present disclosure, such as upper, lower, front, rear, left, right, inside, outer, side, etc., are only directions with reference to the accompanying drawings, so that the used directional terms are used to describe and understand the present disclosure, but not to limit the present disclosure. In the drawings, components with similar structures are labeled by the same numerals.

A method for manufacturing an array substrate is provided in the present disclosure to solve the problem of molybdenum metal residue caused by less etching time of metal lines during a wet etching process in the manufacturing process of an array substrate. The present embodiment can improve the defect.

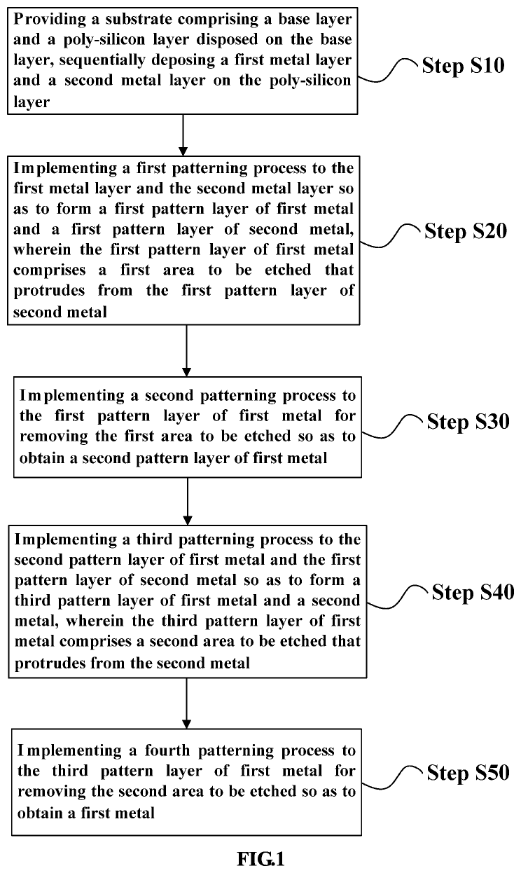

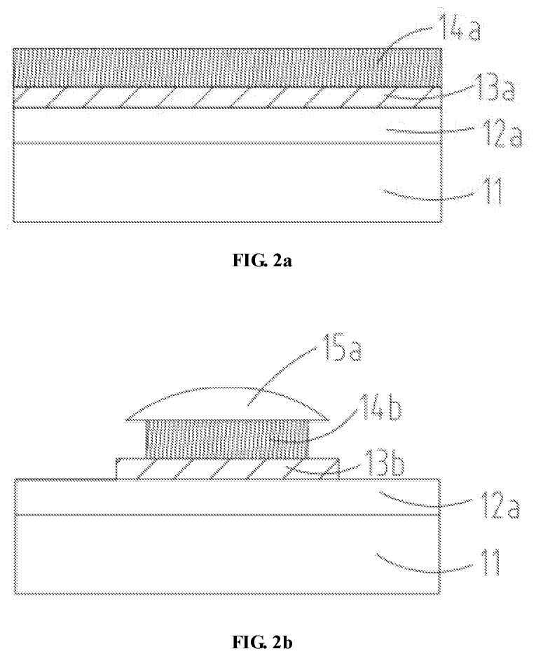

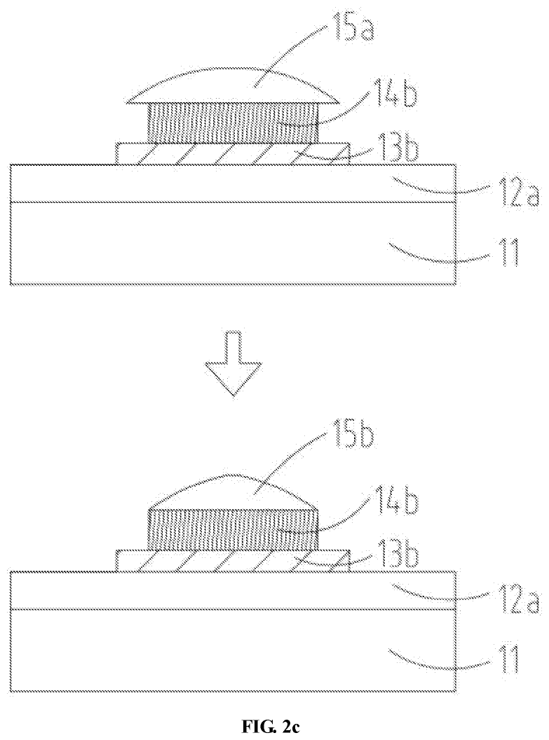

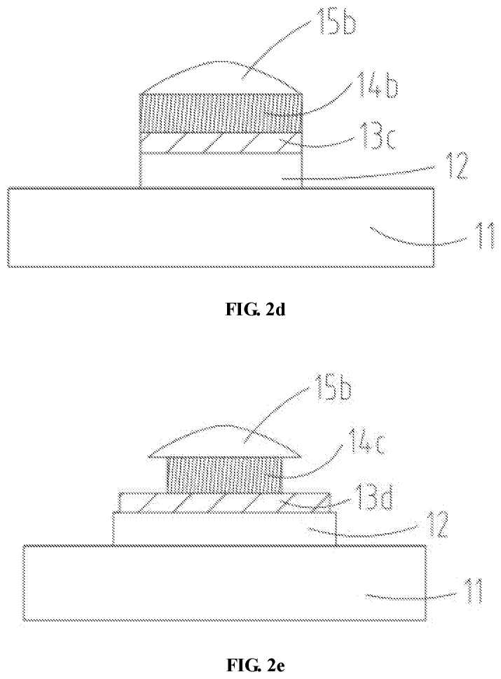

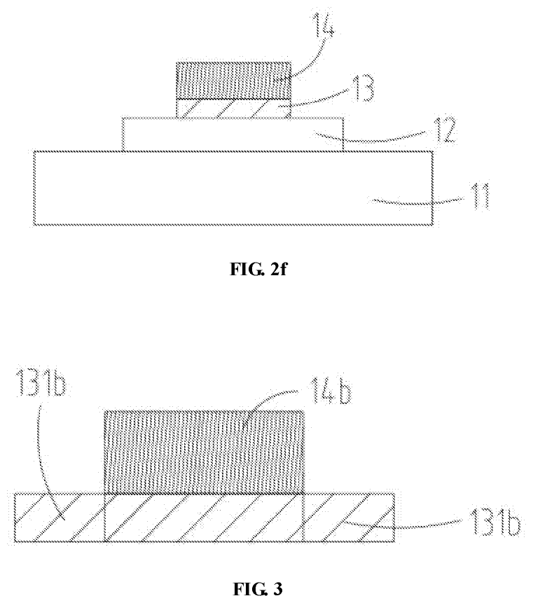

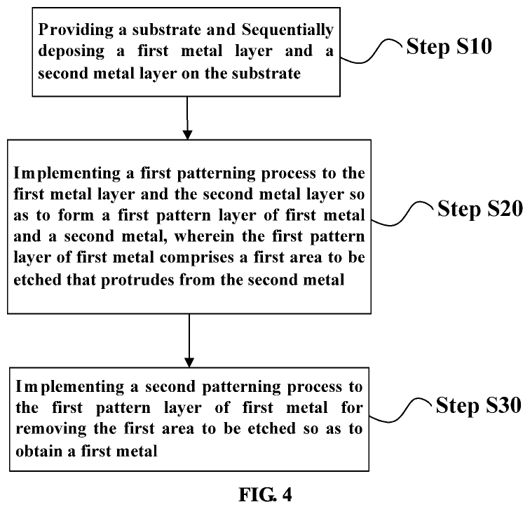

FIG. 1 is a flowchart illustrating a method for manufacturing an array substrate according to one embodiment of the present disclosure; FIGS. 2a to 2f are structural views of an array substrate in manufacturing process according to one embodiment of the present disclosure; FIG. 3 is a structural view of one metal line in step S20 in the present disclosure; and FIG. 4 is a flowchart illustrating a method for manufacturing an array substrate according to another embodiment of the present disclosure.

Hereinafter, the present disclosure is described in detail with reference to specific embodiments and the attached drawings.

As shown in FIG. 1, the present disclosure provides a method for manufacturing an array substrate, including the following steps:

S10, providing a substrate 1 comprising a base layer 11 and a poly-silicon layer 12a disposed on the base layer 11, sequentially deposing a first metal layer 13a and a second metal layer 14a on the poly-silicon layer 12a, as shown in FIG. 2a.

Specifically, the preparation material of the first metal layer 13a is molybdenum, and the preparation material of the second metal layer 14a is copper. It can be understood that the preparation materials of the first metal layer 13a and the second metal layer 14a are not limited to the said materials but can also be other common metal materials.

S20 includes implementing a first patterning process to the first metal layer 13a and the second metal layer 14a to form a first pattern layer of first metal 13b and a first pattern layer of second metal 14b, as shown in FIG. 2b. And, after the first patterning process, the first pattern layer of second metal 13b contains a first area to be etched 131b that protrudes from the first pattern layer of second metal 14b, as shown in FIG. 3.

Specifically, as shown in FIG. 3, in step S20, the first pattern layer of second metal 13b contains: a reserved area and the first area to be etched 131b, wherein the reserved area is an area where the first pattern layer of first metal 13b overlaps with the first pattern layer of second metal 14b, and the first area to be etched 131b is the rest area of the first pattern layer of second metal 14b excluding the reserved area. It can be understood that the first area to be etched is the unetched area of the first pattern layer of second metal 14b.

It should be understood that in the present disclosure, etching time of the first patterning process to the first metal layer 13a and the second metal layer 14a by a wet etching process can be shorten when implementing a wet etching process to the first metal layer 13a and the second metal layer 14a, such that there is no problem of breakage of metal lines caused by excessively narrow width of metal lines. However, since the time of the wet etching process is less than that in a conventional metal wire preparation process, which leads to an incomplete etching of the second metal layer, residual area of the second metal layer, namely the first area to be etched and the second area to be etched of the second metal layer in different states, is then removed in a subsequent process by a dry etching process to effectively solve the aforementioned problems.

Further, as shown in FIG. 2c, a first photoresist layer 15a, which contains an edge area (not shown) protruding from the third metal layer, is disposed on a surface of the third metal layer 14b after implementing the first wet etching process to the substrate 1;

Step S20 further includes: ashing the first photoresist layer 15a to remove the edge area of the first photoresist layer 15b after implementing the first patterning process to the first metal layer 13b and the second metal layer 14b.

The purpose of this step is to remove a portion of the first photoresist layer 15a that is above and corresponds to the first etching region 131, to prepare for etching away the first region to be etched 131 of the first metal layer 13b.

As shown in FIG. 2d, S30 includes implementing a second patterning process to the first pattern layer of first metal 13b for removing the first area to be etched 131b so as to obtain a second pattern layer of first metal 13c.

Step S30 further includes: implementing the second patterning process to the first pattern layer of first metal 13b for patterning the poly-silicon layer 12a when removing the first area to be etched 131b, so as to obtain a patterned poly-silicon layer 12.

Specifically, the first patterning process and the third patterning process are wet etching processes, and the second patterning process and the fourth patterning process are dry etching processes.

In one embodiment of the present disclosure, a dry etching process is a process etching metal layers by etching gases.

Specifically, in step S30, etching the first pattern layer of first metal 13b with etching gases to remove the first area to be etched 131b;

wherein the etching gases contain a first gas and a second gas, the first gas is at least one of carbon tetrafluoride, chlorotrifluoromethane and dichlorodifluoromethane, and the second gas is oxygen.

As shown in FIG. 2e, S40 includes implementing a third patterning process to the second pattern layer of first metal 13c and the first pattern layer of second metal 14b to form a third pattern layer of first metal 13d and a second pattern layer of second metal 14c (namely a second metal 14), wherein the third pattern layer of first metal 13d contains a second area to be etched (not shown) protruding from the second metal, referring to the illustrated parts in step S20 for details.

Since the operating principle of step S40 is similar to that of step S20, related operating principle of step S40 is referred to the operating principle of step S20, and details are not described herein.

Preferably, in step S40, implementing a third patterning process to the second pattern layer of first metal 13c and the first pattern layer of second metal 14b, wherein a second photoresist layer 15b containing an edge area that protrudes from the second metal layer 14 is disposed on a surface of first pattern layer of second metal 14b;

Step S40 further includes: implementing the third patterning process to the second pattern layer of first metal 13c and the second pattern layer of second metal 14b, ashing the second photoresist layer 15b to remove the edge area of the second photoresist layer 15c.

Preferably, in step S40, disposing a second photoresist layer 15b on a surface of the second pattern layer of first metal 13c after implementing the third patterning process to the second pattern layer of first metal 13c and the first pattern layer of second metal 14b;

step S40 further includes: stripping the second photoresist layer 15b after implementing the third patterning process to the second pattern layer of first metal 13c and the first pattern layer of second metal 14b.

As shown in FIG. 2f, S50 includes implementing a fourth patterning process to the third pattern layer of first metal, to remove and form the second area to be etched of the third pattern layer of first metal 13d;

Specifically, step S50 includes:

etching the third pattern layer of first metal 13d with etching gases to remove the second area to be etched;

wherein the etching gases contain a first gas and a second gas, the first gas is at least one of carbon tetrafluoride, chlorotrifluoromethane and dichlorodifluoromethane, and the second gas is oxygen.

Wherein the array substrate includes metal lines composed of the first metal 13 and the second metal 14.

Specifically, the metal lines are source-drain metal lines.

According to another aspect of the present disclosure, a method for manufacturing an array substrate is provided as shown in FIG. 4, which includes: step S10, providing a substrate, and sequentially deposing a first metal layer and a second metal layer on the substrate;

step S20, implementing a first patterning process to the first metal layer and the second metal layer so as to form a first pattern layer of first metal and a second metal, wherein the pattern layer of first metal contains a first area to be etched that protrudes from the first pattern layer of second metal; and

step S30, implementing a second patterning process to the first pattern layer of first metal for removing the first area to be etched so as to obtain a first metal;

wherein the array substrate includes gate metal lines composed of the first metal and the second metal.

Advantageous effect of the present disclosure is to provide an array substrate and manufacturing method thereof, in which residual molybdenum in metal lines is removed by dry etching for reducing the etching time of metal lines during a wet etching process as well as the risk of molybdenum residue, such that the problem of breakage of metal lines caused by excessively narrow width of metal lines can be avoided.

The present disclosure has been described with relative embodiments which are examples of the present disclosure only. It should be noted that the embodiments disclosed are not the limit of the scope of the present disclosure. Conversely, modifications to the scope and the spirit of the claims, as well as the equal of the claims, are within the scope of the present disclosure.

1. A method for manufacturing an array substrate, comprising the following steps:
S10, providing a substrate comprising a base layer and a poly-silicon layer disposed on the base layer, and then sequentially deposing a first metal layer and a second metal layer on the poly-silicon layer;
S20, implementing a first patterning process to the first metal layer and the second metal layer so as to form a first pattern layer of first metal and a first pattern layer of second metal, wherein the first pattern layer of first metal comprises a first area to be etched that protrudes from the first pattern layer of second metal;
S30, implementing a second patterning process to the first pattern layer of first metal for removing the first area to be etched so as to obtain a second pattern layer of first metal;
S40, implementing a third patterning process to the second pattern layer of first metal and the first pattern layer of second metal so as to form a third pattern layer of first metal and a second metal, wherein the third pattern layer of first metal comprises a second area to be etched that protrudes from the second metal; and
S50, implementing a fourth patterning process to the third pattern layer of first metal for removing the second area to be etched so as to obtain a first metal;
wherein the array substrate comprises metal lines composed of the first metal and the second metal, and the metal lines are source-drain metal lines.

2. The method for manufacturing an array substrate according to claim 1, wherein a manufacturing of material of the first metal is molybdenum, and a manufacturing material of the second metal is copper.

3. The method for manufacturing an array substrate according to claim 1, wherein a first photoresist layer comprising an edge area that protrudes from the first pattern layer of second metal is disposed on a surface of the first pattern layer of second metal after implementing the first patterning process to the first metal layer and the second metal layer in step S20, and,
step S20 further comprises ashing the first photoresist layer to remove the edge area of the first photoresist layer after implementing the first patterning process to the first metal layer and the second metal layer.

4. The method for manufacturing an array substrate according to claim 1, wherein step S30 further comprises: implementing the second patterning process to the first pattern layer of first metal so as to pattern the poly-silicon layer when removing the first area to be etched.

5. The method for manufacturing an array substrate according to claim 1, wherein step S30 includes:
etching the first pattern layer of first metal with etching gases to remove the first area to be etched, and,
wherein the etching gases contain a first gas and a second gas, the first gas is at least one of carbon tetrafluoride, chlorotrifluoromethane and dichlorodifluoromethane, and the second gas is oxygen.

6. The method for manufacturing an array substrate according to claim 1, wherein a second photoresist layer is disposed on a surface of the third pattern layer of first metal after implementing the third patterning process to the second pattern layer of first metal and the first pattern layer of second metal in step S40, and,
step S40 further comprises: implementing the third patterning process to the second pattern layer of first metal and the first pattern layer of second metal, and stripping the second photoresist layer.

7. The method for manufacturing an array substrate according to claim 1, wherein the first patterning process and the third patterning process are wet etching processes, and the second patterning process and the fourth patterning process are dry etching processes.

8. The method for manufacturing an array substrate according to claim 1, wherein step S50 includes:
etching the third pattern layer of first metal with etching gases to remove the second area to be etched, and,
wherein the etching gases contain a first gas and a second gas, the first gas is at least one of carbon tetrafluoride, chlorotrifluoromethane and dichlorodifluoromethane, and the second gas is oxygen.

9. A method for manufacturing an array substrate, comprising:
step S10, providing a substrate, and sequentially deposing a first metal layer and a second metal layer on the substrate;
step S20, implementing a first patterning process to the first metal layer and the second metal layer so as to form a first pattern layer of first metal and a second metal, wherein the first pattern layer of first metal comprises a first area to be etched that protrudes from the second metal; and
step S30, implementing a second patterning process to the first pattern layer of first metal for removing the first area to be etched so as to obtain a first metal;
wherein the array substrate comprises gate metal lines composed of the first metal and the second metal.

10. A method for manufacturing an array substrate, comprising the following steps:
S10, providing a substrate comprising a base layer and a poly-silicon layer disposed on the base layer, sequentially deposing a first metal layer and a second metal layer on the poly-silicon layer;
S20, implementing a first patterning process to the first metal layer and the second metal layer so as to form a first pattern layer of first metal and a first pattern layer of second metal, wherein the first pattern layer of first metal comprises a first area to be etched that protrudes from the first pattern layer of second metal;
S30, implementing a second patterning process to the first pattern layer of first metal for removing the first area to be etched so as to obtain a second pattern layer of first metal;
S40, implementing a third patterning process to the second pattern layer of first metal and the first pattern layer of second metal so as to form a third pattern layer of first metal and a second metal, wherein the third pattern layer of first metal comprises a second area to be etched that protrudes from the second metal; and
S50, implementing a fourth patterning process to the third pattern layer of first metal for removing the second area to be etched so as to obtain a first metal;
wherein the array substrate comprises metal lines composed of the first metal and the second metal.

11. The method for manufacturing an array substrate according to claim 10, wherein a manufacturing of material of the first metal is molybdenum, and a manufacturing material of the second metal is copper.

12. The method for manufacturing an array substrate according to claim 10, wherein a first photoresist layer comprising an edge area that protrudes from the first pattern layer of second metal is disposed on a surface of the first pattern layer of second metal after implementing the first patterning process to the first metal layer and the second metal layer in step S20, and,
step S20 further comprises ashing the first photoresist layer to remove the edge area of the first photoresist layer after implementing the first patterning process to the first metal layer and the second metal layer.

13. The method for manufacturing an array substrate according to claim 10, wherein step S30 further comprises implementing the second patterning process to the first pattern layer of first metal so as to pattern the poly-silicon layer when removing the first area to be etched.

14. The method for manufacturing an array substrate according to claim 10, wherein step S30 includes:
etching the first pattern layer of first metal with etching gases to remove the first area to be etched, and,
wherein the etching gases contain a first gas and a second gas, the first gas is at least one of carbon tetrafluoride, chlorotrifluoromethane and dichlorodifluoromethane, and the second gas is oxygen.

15. The method for manufacturing an array substrate according to claim 10, wherein a second photoresist layer is disposed on a surface of the third pattern layer of first metal after implementing the third patterning process to the second pattern layer of first metal and the first pattern layer of second metal in step S40, and,
step S40 further comprises: implementing the third patterning process to the second pattern layer of first metal and the first pattern layer of second metal, and stripping the second photoresist layer.

16. The method for manufacturing an array substrate according to claim 10, wherein the first patterning process and the third patterning process are wet etching processes, and the second patterning process and the fourth patterning process are dry etching processes.

17. The method for manufacturing an array substrate according to claim 10, wherein step S50 includes:
etching the third pattern layer of first metal with etching gases to remove the second area to be etched, and,
wherein the etching gases contain a first gas and a second gas, the first gas is at least one of carbon tetrafluoride, chlorotrifluoromethane and dichlorodifluoromethane, and the second gas is oxygen.
